(19) United States
(12) Patent Application Publication
(10) Pub. No.: US 2023/0334022 A1
(43) Pub. Date: Oct. 19, 2023

(54) SYSTEM AND METHOD FOR PROCESSING AND STORAGE OF A TIME-SERIES DATA STREAM

(71) Applicant: THE HOSPITAL FOR SICK CHILDREN, Toronto (CA)

(72) Inventors: Andrew GOODWIN, Toronto (CA); Robert GREER, Toronto (CA); Peter LAUSSEN, Toronto (CA); Anirudh THOMMANDRAM, Toronto (CA); Mjaye MAZWI, Toronto (CA)

(21) Appl. No.: 17/659,195

(22) Filed: Apr. 14, 2022

(51) Int. Cl. G06F 16/174

(52) U.S. Cl. CPC G06F 16/1744

(57) ABSTRACT

There is provided a system and method for processing and storage of a time-series data stream. The method including: separating an input time-series data stream into a value array and a time array; segmenting the value array into blocks, each block including a plurality of consecutive values; performing iterations of delta encoding on the values in each block; organizing multiple delta encoded blocks in an output file structure, the output file structure further comprising the time array associated with the values in the block and a block header, the block header including: the number of values in the block; initial values for the delta encoding; and the number of iterations of delta encoding applied on the block; and outputting the multiple blocks in the output file structure.

### TECHNICAL FIELD

The present invention relates to compression and indexing of high frequency data streams. A domain specific compression and indexing approach has been developed that exploits characteristics of such signals.

### BACKGROUND

A large amount of heterogeneous data is generated as part of the process of patient care. Such multimodal data streams are integrated and utilized particularly by clinicians in the intensive care environment to understand patients' clinical condition and response to treatment. There has been an increase in research approaches that incorporate these kinds of data into analysis. One of these data types is physiological waveform data, which is generated by interaction of biological systems with technological devices. These information rich streams are sampled and displayed by medical devices and typically sampled at frequencies up to 1000 Hz. These waveforms are produced, for example, by continuously measuring mechanical pressures within the arteries as an arterial blood pressure (ABP) waveform. Other examples of waveform data collected in an intensive care environment include electrocardiograms (ECG), electroencephalograms (EEG), ventilator pressure-volume loops, oxygen saturation and pulse pressure waveform (pulse oximetry, plethysmography).

Physiological waveforms are continuously monitored in environments such as the intensive care unit where their density, continuity and granularity provide an optimal means of longitudinally monitoring patients at risk of sudden or unpredictable deterioration. These individual waveform signals contain information which can facilitate diagnosis. For example, many quantitative physiological descriptors can be extracted from an ECG waveform including heart rate (HR) and heart rate variability (HRV). Also, the waveform morphology itself can be used to diagnose an abnormal heart rhythm. The interactions between these signals can also shed light on coupled physiological subsystems that have the potential to modify each other's behavior in a clinically relevant manner. An example of this coupling of physiological subsystems are cardiopulmonary interactions that measure interactions between the lungs and the cardiovascular system.

Despite the potential utility for research and clinical purposes, storage of physiological waveform data for retrospective analysis presents significant challenges. Ironically, the complexity and granularity that makes this such an appealing data type for analysis also means that the resultant data can be very large, and therefore becomes expensive to store and complicated to manage. Thus, collating archives of usable information in a clinical setting where comprehensive data collection is difficult presents a significant challenge for database administrators.

### SUMMARY

In an aspect, there is provided a method for processing and storage of a time-series data stream, the method executed on one or more processing units, the method comprising: receiving the input time-series data stream; separating the input time-series data stream into a value array storing the values at each timepoint in the time-series data stream and a time array storing the time associated with each stored value; segmenting the value array into blocks, each block comprising a plurality of consecutive values; performing iterations of delta encoding on the values in each block; organizing multiple delta encoded blocks in an output file structure, the output file structure further comprising the time array associated with the values in the block and a block header, the block header comprising: the number of values in the block; initial values for the delta encoding; and the number of iterations of delta encoding applied on the block; and outputting the multiple blocks in the output file structure.

In a particular case of the method, the method further comprising determining an entropy of each iteration of delta encoding, and wherein the iteration with lowest entropy organized into multiple delta encoded blocks.

In another case of the method, the entropy is determined using Shannon entropy.

In yet another case of the method, the method further comprising determining a range of values in the selected array and determining a data type to store the values based on the determined range.

In yet another case of the method, the method further comprising compressing the delta encoded blocks using a further compression technique, and wherein the block header further comprises the further compression technique.

In yet another case of the method, the method further comprising scaling floating point values to integer value using a scaling factor, and wherein the block header further comprises the scaling factor.

In yet another case of the method, the method further comprising storing discontinuities in the time array as an array of intervals.

In yet another case of the method, the array of intervals is stored as a binary structure for use as an index.

In yet another case of the method, the output file structure further comprises the array of intervals.

In yet another case of the method, the discontinuities include occurrences in the time array where a pair of subsequent times are greater than a defined sample frequency.

In another aspect, there is provided a system for processing and storage of a time-series data stream, the system comprising one or more processing units and a data storage, the one or more processing units receiving instructions from the data storage to execute: an input module to receive the input time-series data stream; a compression module to: separate the input time-series data stream into a value array storing the values at each timepoint in the time-series data stream and a time array storing the time associated with each stored value; segment the value array into blocks, each block comprising a plurality of consecutive values; perform iterations of delta encoding on the values in each block; and organize multiple delta encoded blocks in an output file structure, the output file structure further comprising the time array associated with the values in the block and a block header, the block header comprising: the number of values in the block; initial values for the delta encoding; and the number of iterations of delta encoding applied on the block; and an output module to output the multiple blocks in the output file structure.

In a particular case of the system, the compression module further determines an entropy of each iteration of delta encoding, and wherein the iteration with lowest entropy organized into multiple delta encoded blocks.

In another case of the system, the entropy is determined using Shannon entropy.

In yet another case of the system, the compression module further determines a range of values in the selected array and determining a data type to store the values based on the determined range.

In yet another case of the system, the compression module further compresses the delta encoded blocks using a further compression technique, and wherein the block header further comprises the further compression technique.

In yet another case of the system, the compression module further scales floating point values to integer value using a scaling factor, and wherein the block header further comprises the scaling factor.

In yet another case of the system, the compression module further stores discontinuities in the time array as an array of intervals.

In yet another case of the system, the array of intervals is stored as a binary structure for use as an index.

In yet another case of the system, the output file structure further comprises the array of intervals.

In yet another case of the system, the discontinuities include occurrences in the time array where a pair of subsequent times are greater than a defined sample frequency.

### DESCRIPTION OF THE DRAWINGS

An embodiment of the present invention will now be described by way of example only with reference to the accompanying drawings, in which:

FIG. 1 is a block diagram showing a system for processing and storage of a time-series data stream, according to an embodiment;

FIG. 2 is a flowchart showing a method for processing and storage of a time-series data stream, according to an embodiment;

FIG. 3 is a diagram illustrating an example file structure in accordance with the system of FIG. 1;

FIG. 4 is a chart illustrating an example composite signal in accordance with the system of FIG. 1; and

FIG. 5 illustrates a method for data retrieval, in accordance with an embodiment.

### DETAILED DESCRIPTION

Embodiments will now be described with reference to the figures. For simplicity and clarity of illustration, where considered appropriate, reference numerals may be repeated among the figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, well-known methods, procedures and components have not been described in detail so as not to obscure the embodiments described herein. Also, the description is not to be considered as limiting the scope of the embodiments described herein.

Any module, unit, component, server, computer, computing device, mechanism, terminal or other device exemplified herein that executes instructions may include or otherwise have access to computer readable media such as storage media, computer storage media, or data storage devices (removable and/or non-removable) such as, for example, magnetic disks, optical disks, or tape. Computer storage media may include volatile and non-volatile, removable and non-removable media implemented in any method or technology for storage of information, such as computer readable instructions, data structures, program modules, or other data. Examples of computer storage media include RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by an application, module, or both. Any such computer storage media may be part of the device or accessible or connectable thereto. Any application or module herein described may be implemented using computer readable/executable instructions that may be stored or otherwise held by such computer readable media and executed by the one or more processors.

The goal of the present embodiments is to apply modern time series compression approaches to the problem of physiological waveform storage and retrieval. Traditional database approaches are not suitable for storing such large volumes of time series information.

Continuous high-frequency physiologic signals are characterized by being large in volume and high in variability. Numerous database systems and approaches have been developed specifically for storage of time series data, and among these, domain specific approaches are generally able to outperform more generic timeseries compression approaches. For example, a domain specific approach may target floating-point or integer values; regularly sampled time series or aperiodic data; and long-term vs short-term storage.

The general properties of physiological data streams include:
Highly variable sample frequency—ranging from 0.0003 to 1000 Hz. Sampling frequencies range across more than six orders of magnitude.
Multiple variables—Physiological time series often consist of multiple variables that are collected and accessed together. A patient in the ICU may be monitored by several medical devices simultaneously and may generate several dozen simultaneous and distinct data streams of information.
Low precision—Many physiological signals, particularly the high-volume waveform data streams, are produced by Analog-to-Digital Converters (ADCs) are integers with a precision of 16 bits or fewer.
Temporal correlation—High frequency physiological sampling often involves using a sample rate much higher than the rate of change od the underlying variable. For example, a relatively rapid rise in heart rate may take 30 seconds to rise from 100 to 115 BPM but would be sampled once per second throughout that transition.

As part of the design process, it was established that an ideal physiological waveform data database would have the following characteristics:
Compact Representation—The ability should exist to compress waveform data to a small size that is cost-effective to store long term—i.e., high compression ratio.
High Fidelity—Information should be stored directly to disk exactly as supplied from the monitors/sensors, with no loss of information—i.e., lossless compression.
Long Term Storage—Stored data should be retained indefinitely—i.e., cost-effective long-term storage.
Indexing—A structure should be imposed that permits creation of metadata that facilitates quality control and research cohort identification without the need to access the raw data directly—i.e., efficient data exploration.
Efficient Retrieval—Data should be able to be retrieved rapidly for use in analysis and discovery. Programmatic data retrieval should be enabled and optimized for parallel and distributed computing applications—i.e., rapid decompression and data egress.

Recently there has been a push towards NoSQL type architectures for storage of time series data. Such databases exploit inherent redundancies in sequences of values in the time series to provide more compact representations of the data. In these systems, intervals of contiguous data are compressed together into a single chunk or block. This facilitates a wider range of compression options, and allows indices to be more coarsely constructed, reducing overhead and leading to lower latency queries.

Medical devices sample and deliver physiological waveforms in a way that makes delta encoding particularly effective. Physiological waveforms are often smoothed and pre-processed in the sensor or monitor such that iterative application of delta encoding results in a more compressible byte stream. Delta encoding records an initial value, and then only stores the difference between subsequent values. The array of delta encoded values is generally centered around zero and will have a tighter distribution than the original data. This approach results in lossless compression when applied to arrays of integers. In the present approach, each signal type was profiled to identify the optimal sequence of pre-processing steps, for example selecting the number of iterations of delta encoding to apply.

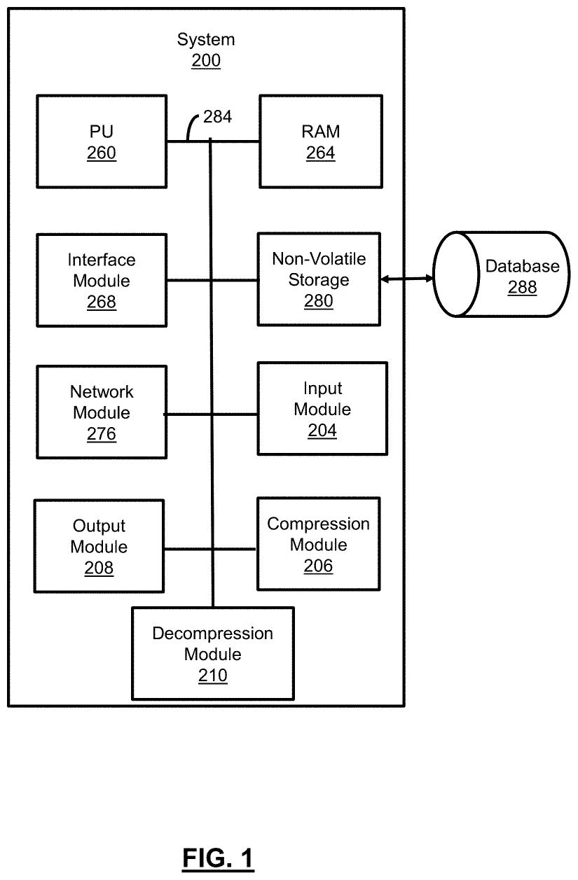

FIG. 1 illustrates a schematic diagram of a system 200 for processing and storage of a time-series data stream, according to an embodiment. As shown, the system 200 has a number of physical and logical components, including a processing unit (“PU”) 260 comprising one or more processors, random access memory (“RAM”) 264, an interface module 268, a network module 276, non-volatile storage 280, and a local bus 284 enabling PU 260 to communicate with the other components. PU 260 can include one or more processors. RAM 264 provides relatively responsive volatile storage to PU 260. In some cases, the system 200 can be in communication with a device, for example, a physiological data source, via, for example, the interface module 268. The interface module 268 enables input to be provided; for example, directly via a user input device, or indirectly, for example, via an external device. The interface module 268 also enables output to be provided; for example, directly via a user display, or indirectly, for example, sent over the network module 276. The network module 276 permits communication with other systems or computing devices; for example, over a local area network or over the Internet. Non-volatile storage 280 can store an operating system and programs, including computer-executable instructions for implementing the methods described herein, as well as any derivative or related data. In some cases, this data can be stored in a database 288. During operation of the system 200, the operating system, the programs and the data may be retrieved from the non-volatile storage 280 and placed in RAM 264 to facilitate execution. In other embodiments, any operating system, programs, or instructions can be executed in hardware, specialized microprocessors, logic arrays, or the like. In an embodiment, the PU 260 can be configured to execute an input module 204, a compression module 206, an output module 208, and a decompression module 210. In further cases, functions of the above modules can be combined or executed on other modules. In some cases, functions of the above modules can be executed on remote computing devices, such as centralized servers and cloud computing resources communicating over the network module 276.

The present system utilizes a custom designed file format that segments the signals into a series of intervals of user defined length. Each individual block of data may be pre-processed in a variety of ways to decrease its entropy and therefore increase its compressibility. The pre-processed arrays are then further compacted using a third-party compression algorithm.

There is provided a method 300 for processing and storage of a time-series data stream in an output data structure, according to an embodiment.

In an embodiment of the method 300, the method comprises:
the input module 204 receives the input time-series data stream;
the compression module 206 separates the input time-series data stream into a value array storing the values at each timepoint in the time-series data stream and a time array storing the time associated with each stored value;
the compression module 206 segments the value array into blocks, each block comprising a plurality of consecutive converted values;
the compression module 206 performs iterations of delta encoding on the converted values in each block until an iteration with lowest entropy is reached;
the compression module 206 organizes multiple delta encoded blocks in an output file structure, the file structure further comprising the associated time array for the values in the block and a block header, the block header comprising: the number of values in the block; initial values for the delta encoding; and the number of iterations of delta encoding applied on the block; and
the output module 208 outputs the multiple blocks in the output file structure to the interface module 268, to the database 288 or to the network module 276.

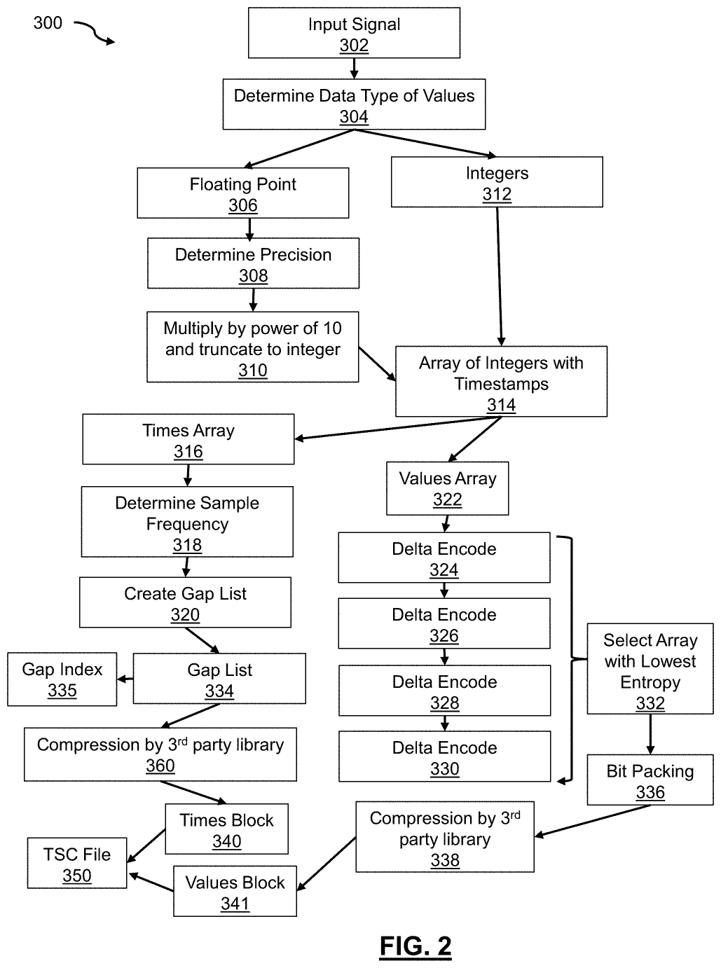

FIG. 2 illustrates a flow diagram of an embodiment of the method 300 for processing and storage into an output file structure (referred to as ‘TSC’ file format). At flowchart-block 302, a stream of data (a signal) is collected from a sensor by the input module 204 via the interface module 268. Each value in the signal has an associated timestamp. The data is an ordered timeseries but may contain gaps of varying sizes.

At flowchart-block 304, the compression module 206 splits the data into two different data processing pathways. A first pathway for floating point values, as they generally require additional pre-processing steps (flowchart-blocks 306, 308 and 310), and the other pathway for integers (flowchart-block 312).

For floating-point values, the compression module 206 determines the precision of the data stream (flowchart-block 308). Many data streams have a known precision, for example, a temperature sensor that can only sample temperatures to the nearest 0.1 degrees Celsius. In this example, the values are multiplied by a power of 10, (i.e., 10n, where n is the precision of the sensor, and hence, the number of significant figures in the floating-point data). The resulting value is rounded to the nearest integer.

At flowchart-block 314, the data has been transformed into an array of integers, and each value has an associated timestamp. These time-value pairs are split into two separate arrays, one for times and one for values. These arrays will be of equal length.

For the values array (flowchart-block 322), the array is iteratively delta encoded (flowchart-blocks 324, 326, 328, and 330) by the compression module 206. Delta encoding records the initial value from the original values array, and then generates a second array containing only the differences between subsequent values in the original array. Iterative delta encoding means that this process is repeated several times, where the output of one delta encoding process becomes the input for the next iteration of delta encoding. For example, the output of the first delta encoding process in flowchart-block 324 becomes the input array for the next iteration of delta encoding (flowchart-block 326).

In this embodiment, a Shannon entropy of the array generated by each iteration of the delta encoding is determined by the compression module 206, and the array with the lowest Shannon entropy is selected for subsequent processing (flowchart-block 332). In further cases, other suitable entropy determinations can be used.

In flowchart-block 332, the range of values in the selected array is determined by the compression module 206 and an appropriate data type is used to store the values. For example, if the range of values is <=256 then a 1-byte integer can be used. If the range of the delta encoded array is less than 2\hat{ }16 then a 2-byte integer data type is used to store the values; and so on.

The binary packed data generated by flowchart-block 336 is compressed by the compression module 206 using a suitable compression technique. For example, GZip, ZStandard, BZip, and the like.

At flowchart-block 341, the initial values required to regenerate the raw data from the delta encoded array are stored in a values block of an output file having the TSC file structure.

The array of time values, generated at flowchart-block 316 by the compression module 206, has the same number of elements as the values array. The sample frequency can be previously determined or defined by the user (flowchart-block 318). Any and all discontinuities (referred to as “gaps”) in the times can be detected and recorded (flowchart-block 320). A “gap” is defined as a pair of subsequent times that is not equal to the defined sample frequency for that signal.

The list of detected gaps is recorded as an array of intervals by the compression module 206 (flowchart-block 334). This list of intervals is saved into an external binary structure (flowchart-block 335) for later retrieval and use as an index, and can also be compressed by a suitable compression technique (flowchart-block 360), such as those described herein.

The compressed list of gaps is stored in a times block of the output file having the TSC file structure (flowchart-block 340).

At flowchart-block 350, the output module 208 outputs the output file with the TSC file structure.

The input module 204 receives an input time-series data stream; for example, a data stream comprising the physiological signal. The compression module 206 separates each sequence of time-value pairs into two distinct arrays of equal length. One array contains the values while another array of equal length stores the time associated with each value in the first array. Times are stored explicitly so that gaps in the data can be faithfully represented. This differs from other approaches that implicitly store time by assuming a constant sample rate. The number of bytes required to store the delta encoded array is determined based on the range of values in the resultant array, and the most compact representation is used for each separate block of data. Binary representations of the delta encoded arrays are subsequently compressed using a third-party compression library such as BZip2 or ZStandard. This additional compression step further reduces the size of each block's payload by applying run length encoding (RLE) and otherwise removing any remaining redundancy in the data representation.

Signals that arrive as floating-point values are converted by the compression module 206 to an integer by multiplying by a power of 10, with the multiplying factor chosen such that the resulting integer is representative of the underlying precision of the data. Ideally the raw integer values collected by the Analog to Digital converters on the various sensors are available directly or can be reverse engineered. These integer values may be subsequently re-scaled to a floating-point representation with relevant units, such as mmHg for pressure waveforms or mV for ECG. The scaling factors required for these conversions are stored in a separate relational database or in the block headers within the TSC file structure; see FIG. 2.

Times and values are thus stored as two separate arrays, with the compression approaches for both arrays tuned for the characteristic continuity and value-to-value correlation of physiological data. Although this data format is generally used for high-frequency physiological data (i.e. waveforms), it can also be used for lower frequency data (e.g., 1 Hz).

If a signal has no gaps, then the sample number can be a function of the time, and vice versa. In this way, continuously sampled data does not need a sophisticated temporal index, as the present system can determine a certain number (n) of samples to find a certain time-point in the data. Physiological data streams can have many gaps of varying sizes, and therefore, this kind of data requires a sophisticated approach to management of gaps and temporal indexing of the data. Such advantageous approach is described in more detail herein.

Physiological signals can generally have a sample rate that is higher than the rate of change of the physiological property they are measuring. This means that subsequent values in the timeseries have a high correlation to one another. For example, if the current heart rate is 120 beats per minute, then there is a high probability that the heart rate one second later will also be 120 beats per minute. The present embodiments can use delta encoding to exploit this value-to-value correlation to achieve a high compression ratio. In this way, the system can be thought of as “tuned” because subsequent values are generally highly correlated, and thus uses delta encoding in pre-processing. Delta encoding is described in more detail herein.

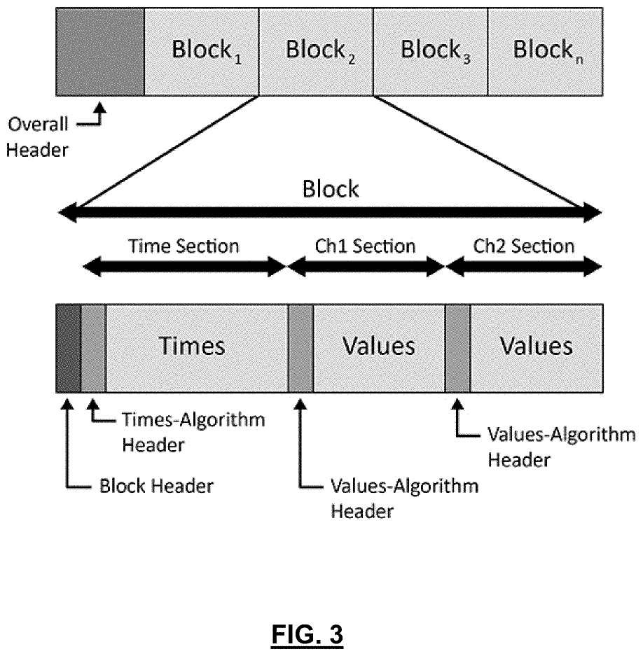

As illustrated in FIG. 3, the system includes a file structure (referred to as ‘TSC’ file format) that allows multiple compressed segments of a signal to be stored in a single file. These segments, called blocks, can vary in size but typically contain between 1000 and 100,000 time-value pairs. The block size parameter is set globally for each signal type when the system is initialized. To access any value (or any sequence of values) within a block the entire block must be decompressed. Use of smaller blocks facilitates more granular access but may result in an increase in handling and container overhead. Longer queries may span multiple blocks, allowing parallelized decompression.

In most cases, each block header contains the information required to decompress that individual block. In this way individual blocks can be passed across a network and decompressed on a remote system. This approach to data transfer reduces the load on a central computing device by offloading the computational load associated with de-compression to other devices (clients) or a distributed computing node.

Information stored in the block header includes the number of elements in the stored arrays, the size of the compressed payload in bytes, the initial values required for reversing the delta encoding, the number of iterations of delta encoding applied, the number of bytes required to store each value in the delta encoded array, any scale factors that might be required to convert the integers back to real-world units, and the type of open-source algorithm employed in the secondary compression stage. Summary statistics such as the number of values, maximum, minimum, mean, and standard deviation of the values, are also stored in the block headers. The main file header lists the number of blocks, the start and end times of each block, and the location (in bytes) of the beginning of each block of data in the file. A single TSC file may contain up to 65,536 blocks.

In order to decompress the data block, the block header includes the initial values, the number of bytes per value, and the type of third-party compression used. If the integer values need to be scaled to real-world units, then the block header will include a scale factor; for example, millimetres of Mercury for pressure measurements. Other values that can be included in the block header can include mean, max, min, and standard deviation of the values in the array contained in the block. Although these statistical descriptors of the data may not be required to decompress the data, they can provide additional insight into the extent and nature of the values contained in the compressed block. The presence of such information in the header can be useful as the values can be very rapidly retrieved without the need to decompress any data, foregoing the need to perform the computationally expensive decompression process.

Each of the compressed files is stored on a secure server, with a folder structure that is organized by date. Details regarding each compressed file are recorded as a row in a relational database. Metadata about the file, such as file size, number of values, statistical properties of the values in the file, and the start and end times of the data stored in that file, are also recorded in the database.

In some cases, device identifiers (“DeviceID”) can be used as the primary key in the database instead of patient IDs. This approach ensures that retrospective adjustments can be made to the admission/discharge information without altering the folder structure or file names. Patients can be mapped to a particular bed space as a function of time via a separate table in the relational database. This association of DeviceID with a bed space can be implemented such that it does not change and is independent of the patient who occupies the bed space. Using the bed name (or DeviceID) as the primary key in the timeseries database allows the system to write the data to disk once only, and any logic required to map a patient to a bed space can be added as an extra layer on top of this data. In this way the raw data written to disk is “immutable” (i.e., it will generally never be changed once it has been written to disk). This is advantageous because it means that the writes are more efficient, and it can be assumed that the system will not be required to do any expensive “update” operations on the large timeseries data.

The system uses the concept of data intervals to delineate contiguous areas of interest in the time series data. Each interval is a period from t1 to t2 for a given deviceID-signal combination. Intervals are useful abstract data types as they often form the foundation for subsequent data requests. An “area of interest” is a subset of data that the current operation is operating on; for example, a visualization system, a data export process, or feeding training data into a machine learning model. An “area of interest” can be any suitable area; for example, a period of time that a clinician wants to visualize, a period of time that a machine learning operation wants to operate on, or the like.

Although the interval may be specified by a user, preferably the interval generation is performed by the processing unit 260 via an automated process, for example, within an application programming interface (API), particularly when accessing large portions of the database. For example, a user or computer program may ask for a list of time intervals where ‘continuous’ 500 Hz ECG Lead II waveform is available for a particular patient. Because the stored data contains many small gaps, this request may return dozens, or indeed thousands or millions of intervals, each indicating a segment of time where data is guaranteed to be available. In this sense the intervals are a property of the dataset, as opposed to a user defined period. A list of intervals can be algorithmically generated when a user defines a partitioning scheme. For example, such a scheme might ask “get all the sections of continuous ECG data and divide them up into intervals of 60 second duration”. In this way, for a given dataset combined with a given partitioning approach, it will generate a unique list of intervals in a deterministic way. In this example, the user defines the partitioning scheme, and the system produces a list of intervals. In an alternative approach, a user can manually specify the start and end points of each interval; but this can become impractical at larger scales.

Interval data structures can be explicitly available to users of the database by design. An interval may be used as a foundation for a subsequent data request, via an automated or manual process. Generally, time intervals are simple data structures; for example, two specified time points time1 and time2. The present embodiments can extend this definition and associate time intervals with a particular signal by also providing information about the bed space (deviceID) and the signal name. In this way, a time interval specifies a period of time for a specific signal. Intervals may also relate to periods of time that span multiple signals; which can be referred to as a “composite signal”. Composite signals are discussed in more detail herein.

Signal Quality Indexes (SQIs) describe some property of the data as a function of time. A suite of SQIs are applied during the data ingest process, these include identification of periods of flat-line signals (perhaps generated by leads being removed from a patient) and clipping waveforms, which may result from a signal amplitude that exceeds the dynamic range of the sensor. These SQIs may be used as constraints when selecting data that result in removal of portions of the signal, introducing additional gaps. For example, this property may describe the noisiness of the data, or the utility of the data in some way. SQIs are typically algorithmically generated, but may also be manually generated. A query may use a SQI as a constraint by allowing a user to exclude portions of the dataset that do not meet the quality requirements for a particular process. For example, a query of the database may request only waveform data that is not a flat line (i.e., contains no information).

Gaps in physiological signals may be due to a variety of reasons including the intrinsic absence of data, networking issues, removal of sensors for cleaning, or as the result of a particular sampling approach. The size of the gaps in the data may range from very small (a few hundred milliseconds) to very large (minutes or hours), so the definition of ‘continuous’ may be variable and context dependent.

Continuity of the signals may be parameterised by defining a concept called ‘gap tolerance’. The API can return a list of continuous intervals where the required continuity (as specified using the gap tolerance parameter) is guaranteed. For example, if the present system requests all intervals of ‘continuous’ data with a gap tolerance of two seconds, then the database will return a list of intervals having time periods from t1 to t2 where each of those intervals is guaranteed not to contain any periods longer than two seconds that do not contain any data. A smaller gap tolerance results in a larger number of intervals, and vice versa.

When generating a list of “continuous” intervals, the present system can read a list of indexed gaps, remove all gaps with a duration less than a predetermined gap tolerance from the list, then generate a new list of intervals from the time periods between the gaps. The resulting list of intervals will be “continuous” with respect to the specified gap tolerance.

Physiological models or analytical techniques may require multiple signals as inputs. These models may be unable to operate unless all necessary signals are available in the input data. For a given application, the present system can request a list of time intervals where all required input signals are available, and where they meet the quality criteria required for that analytical technique. These groups of signals can be referred to as a ‘composite signal’. A composite signal comprises two or more signals from a given bedspace, each of which may have a different specified gap tolerance. Queries to the API can define the list of required signals, and their required gap tolerance, and optionally also constraints as defined by one or more SQIs.

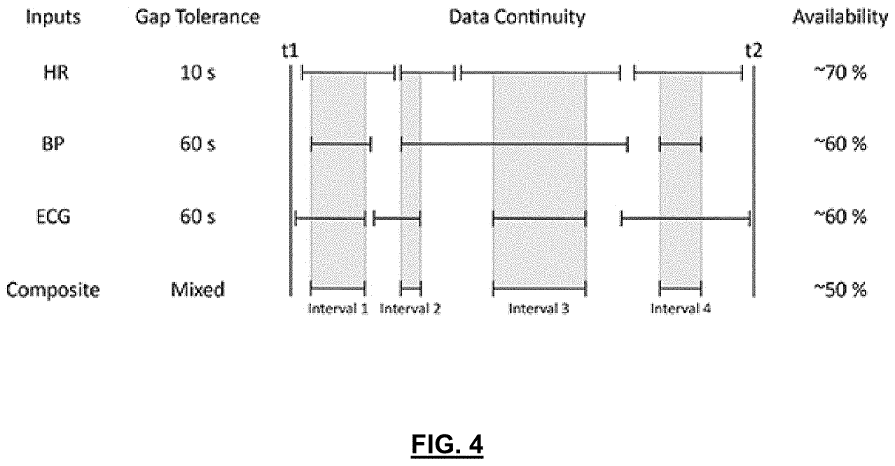

A hypothetical example of a composite signal is shown in FIG. 4. It shows the intervals of continuous time for blood pressure (BP), heart rate (HR), and an electrocardiogram (ECG) waveform, with a gap tolerance of 10 seconds, 60 seconds, and 60 seconds respectively. Note that a different gap tolerance can be specified for each signal. The bars illustrated in FIG. 4 represent regions of time where the data is “continuous”; i.e., where there are no gaps between subsequent values that are larger than a specified gap tolerance. For example, for the blood pressure values shown in FIG. 4, with a gap tolerance of 10 seconds, the bars represent regions where the compression module 206 can guarantee that there will be no longer than 10 seconds between subsequent samples.

The “composite intervals” in this example are defined by the intersection of the input components' continuous time intervals. These intervals can optionally be further subdivided into sub-intervals by providing a parameter that describes the maximum number of time-value pairs that an interval may contain, or by specifying the maximum interval duration. Intervals of this kind, containing multiple signals, may be used as a substrate for training machine learning models.

Once the intervals of time are identified, where data of sufficient quality and continuity is available, a secondary request may be issued to the API requesting the raw data from those times. This two-step approach eliminates the risk of requesting data from a time where no information was available or was of insufficient quality. In the current implementation data requests can be made using, for example, a Representational State Transfer (REST) based API, and data can be returned via hypertext transfer protocol (HTTP) in JavaScript object notation (JSON) format. Alternately, compressed blocks of data may be decompressed directly into RAM, bypassing the computationally expensive process of converting the data to JSON format and parsing the JSON within the application. This direct method of data access is more suited for high performance computing (HPC) applications.

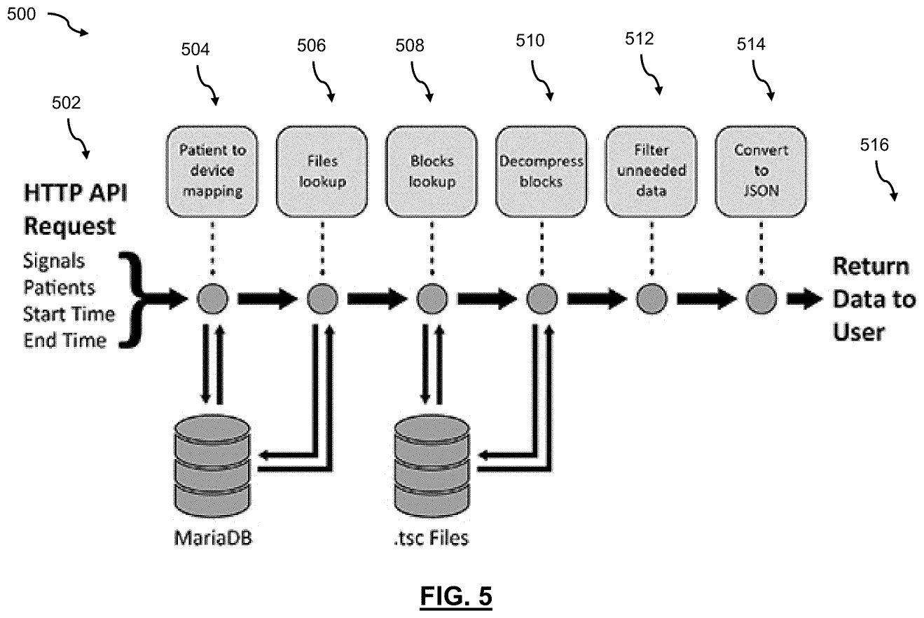

FIG. 5 illustrates a diagram of a method 500 of accessing stored data in the file structure, described herein, by the decompression module 210. In this example, data is retrieved via a hypertext transfer protocol (HTTP) application programming interface (API). Advantageously, this data interface is highly versatile, yet relatively low data throughput, and is suitable for, for example, data exploration, data visualization, and small-scale data export.

At flowchart-portion 502, a HTTP request is received by the input module 204; for example, arriving via a representational state transfer (REST) API server. The request contains information about the patientID, signal type, start time, and end time of the requested data.

At flowchart-portion 504, the patientID and time information is mapped to a bed space using a secondary database table by the decompression module 210. In most cases, this operation can be deliberately separated from the primary timeseries data store so that updates to the patient mapping table can be made in a lean and efficient way, without the need to edit and update large portions of the indexes relating to the raw timeseries data.

At flowchart-portion 506, the decompression module 210 identifies which files might contain the timeseries data being requested. The decompression module 210 performs this identification by querying a table in a relational database. Each row in the database contains a unique file name, and the start time and end time of the data contained in that file. In an example, such database can be MariaDB. This operation may be a single file, or multiple files.

Each file can have the file structure described herein (referred to as TSC) and generally contains multiple, self-contained compressed blocks of information. Each of these blocks covers a period of time, and, in an example, contain between 10,000 and 100,000 values. At flowchart-portion 508, the decompression module 210 reads the file header and identifies which blocks of compressed information match the query constraints. In this way, the decompression module 210 identifies which blocks need to be decompressed.

At flowchart-portion 510, the identified blocks of data are decompressed. In some cases, if multiple blocks are identified, they can be decompressed in parallel. This decompression may be performed by the decompression module 210 on the server or on a client hardware.

At flowchart-portion 512, the decompression module 210 filters unnecessary data from the decompressed data arrays. This operation may be necessary because blocks must be decompressed completely, but the underlying query constraints my not need all the data that has been decompressed.

In some cases, at flowchart-portion 514, the decompression module 210 converts the decompressed timeseries data to JSON (JavaScript Object Notation) format. In other cases, the decompression module 210 can decompress the timeseries data directly into RAM 264, which is a more suitable approach for high performance computing applications.

At flowchart-portion 516, the output module 208 outputs the decompressed data to the user.

Although the present embodiments describe compression with respect to physiological data, it is understood that the approaches described herein can be used with any suitable input data stream. For example, input data signals where at least one of the following is true:
timeseries data is integers, and the size of the data is relatively large;
the sample rate is much higher than the rate of variation of the underlying property being measured;
there is high correlation between subsequent values in the timeseries (i.e., the first, and second, and third, etc., derivatives of the signal have a low entropy); and
the data is regularly sampled but has a wide range of gaps in the data.

The present embodiments would be particularly useful when fragmentation of timeseries data is high (lots of gaps with varying durations) and also where multiple signals need to be retrieved and analyzed simultaneously. The present embodiments would also be particularly useful for analytical approaches that aim to “replay” historical data very rapidly to test different scenarios.

A non-exhaustive list of examples of applications of the present embodiments can include:
Internet of things monitoring.
Movement sensors, such as inertial measurement units (IMU) for gait monitoring, or from a smartphone sensor.
High volume, low frequency physiological monitoring, such as heart rate, from smart devices.
Energy systems, such as battery levels or voltage output, from solar server farms.
Server monitoring information in datacenters (e.g., CPU load, temperature, free disk space, etc.).
Remote sensing timeseries data, such as stream gauges and temperature probes.

Although the invention has been described with reference to certain specific embodiments, various other aspects, advantages and modifications thereof will be apparent to those skilled in the art without departing from the spirit and scope of the invention as outlined in the claims appended hereto. The entire disclosures of all references recited above are incorporated herein by reference.

1. A method for processing and storage of a time-series data stream, the method executed on one or more processing units, the method comprising:
receiving the input time-series data stream;
separating the input time-series data stream into a value array storing the values at each timepoint in the time-series data stream and a time array storing the time associated with each stored value;
segmenting the value array into blocks, each block comprising a plurality of consecutive values;
performing iterations of delta encoding on the values in each block;
organizing multiple delta encoded blocks in an output file structure, the output file structure further comprising the time array associated with the values in the block and a block header, the block header comprising:
the number of values in the block;
initial values for the delta encoding; and
the number of iterations of delta encoding applied on the block; and
outputting the multiple blocks in the output file structure.

2. The method of claim 1, further comprising determining an entropy of each iteration of delta encoding, and wherein the iteration with lowest entropy organized into multiple delta encoded blocks.

3. The method of claim 2, wherein the entropy is determined using Shannon entropy.

4. The method of claim 1, further comprising determining a range of values in the selected array and determining a data type to store the values based on the determined range.

5. The method of claim 1, further comprising compressing the delta encoded blocks using a further compression technique, and wherein the block header further comprises the further compression technique.

6. The method of claim 1, further comprising scaling floating point values to integer value using a scaling factor, and wherein the block header further comprises the scaling factor.

7. The method of claim 1, further comprising storing discontinuities in the time array as an array of intervals.

8. The method of claim 7, wherein the array of intervals is stored as a binary structure for use as an index.

9. The method of claim 8, wherein the output file structure further comprises the array of intervals.

10. The method of claim 7, wherein the discontinuities include occurrences in the time array where a pair of subsequent times are greater than a defined sample frequency.

11. A system for processing and storage of a time-series data stream, the system comprising one or more processing units and a data storage, the one or more processing units receiving instructions from the data storage to execute:
an input module to receive the input time-series data stream;
a compression module to:
separate the input time-series data stream into a value array storing the values at each timepoint in the time-series data stream and a time array storing the time associated with each stored value;
segment the value array into blocks, each block comprising a plurality of consecutive values;
perform iterations of delta encoding on the values in each block; and
organize multiple delta encoded blocks in an output file structure, the output file structure further comprising the time array associated with the values in the block and a block header, the block header comprising:
the number of values in the block;
initial values for the delta encoding; and
the number of iterations of delta encoding applied on the block; and
an output module to output the multiple blocks in the output file structure.

12. The system of claim 11, wherein the compression module further determines an entropy of each iteration of delta encoding, and wherein the iteration with lowest entropy organized into multiple delta encoded blocks.

13. The system of claim 12, wherein the entropy is determined using Shannon entropy.

14. The system of claim 11, wherein the compression module further determines a range of values in the selected array and determining a data type to store the values based on the determined range.

15. The system of claim 11, wherein the compression module further compresses the delta encoded blocks using a further compression technique, and wherein the block header further comprises the further compression technique.

16. The system of claim 11, wherein the compression module further scales floating point values to integer value using a scaling factor, and wherein the block header further comprises the scaling factor.

17. The system of claim 11, wherein the compression module further stores discontinuities in the time array as an array of intervals.

18. The system of claim 17, wherein the array of intervals is stored as a binary structure for use as an index.

19. The system of claim 18, wherein the output file structure further comprises the array of intervals.

20. The system of claim 17, wherein the discontinuities include occurrences in the time array where a pair of subsequent times are greater than a defined sample frequency.
